(19) United States
(12) Patent Application Publication
(10) Pub. No.: US 2022/0052285 A1
(43) Pub. Date: Feb. 17, 2022

(54) SEMICONDUCTOR NANOPARTICLE, COLOR CONVERSION MEMBER INCLUDING THE SEMICONDUCTOR NANOPARTICLE, AND ELECTRONIC APPARATUS INCLUDING THE COLOR CONVERSION MEMBER

(71) Applicants: Samsung Display Co., Ltd., Yongin-si (KR); Research & Business Foundation Sungkyunkwan University, Suwon-si (KR)

(72) Inventors: Sunyoung KWON, Yongin-si (KR); Wanki BAE, Seoul (KR); Keunchan OH, Yongin-si (KR); Hyeokjin LEE, Yongin-si (KR); Junhyuk CHANG, Suwon-si (KR); Hakjune LEE, Suwon-si (KR)

(21) Appl. No.: 17/444,892

(22) Filed: Aug. 11, 2021

(30) Foreign Application Priority Data
Aug. 14, 2020 (KR) 10-2020-0102702

(51) Int. Cl. H01L 51/50; G02F 1/1335

(52) U.S. Cl. CPC H01L 51/502; B82Y 20/00; G02F 1/133514; H01L 51/5036

(57) ABSTRACT

A semiconductor nanoparticle, a color conversion member (including the semiconductor nanoparticle), and an electronic apparatus (including the color conversion member) are provided. The semiconductor nanoparticle includes a core including ZnSe₁₋ₓTeₓ, a middle shell covering the core and including ZnSe and/or ZnSe_{y}S_{1-y}, and an outer shell covering the middle shell and including a Group II-VI compound, wherein 0.2<x≤0.5, 0<y<1, and the semiconductor nanoparticle emits visible light other than blue light.

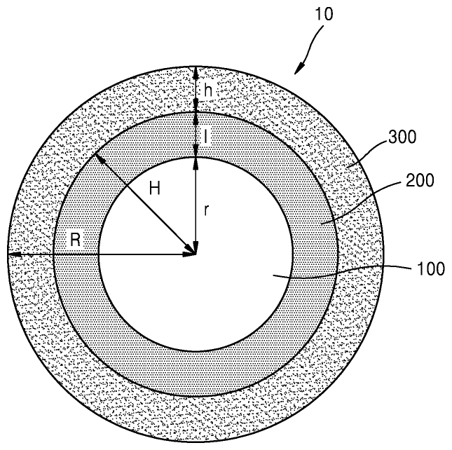

### CROSS-REFERENCE TO RELATED APPLICATION

This application claims priority to and the benefit of Korean Patent Application No. 10-2020-0102702, filed on Aug. 14, 2020, in the Korean Intellectual Property Office, the disclosure of which is incorporated by reference herein in its entirety.

### BACKGROUND

### 1. Field

One or more embodiments relate to a semiconductor nanoparticle, a color conversion member including the semiconductor nanoparticle, and an electronic apparatus including the color conversion member.

### 2. Description of Related Art

Semiconductor nanoparticles, also referred to as quantum dots, are nanocrystals of semiconductor materials, which exhibit a quantum confinement effect. When a quantum dot receives light from an excitation source and reaches an excited energy state, the quantum dot itself emits energy according to a corresponding energy band gap. Even in the case of the same materials, because the wavelengths change according to the particle sizes, light in a desired wavelength range may be obtained by adjusting the sizes of the quantum dots. Because the quantum dots exhibit suitable (e.g., excellent) color purity and high luminescence efficiency, the quantum dots may be applied to various suitable devices or apparatuses.

Lighting apparatuses may be utilized for various suitable applications. For example, lighting apparatuses may be utilized for indoor or outdoor lighting, stage lighting, decorative lighting, and/or backlight units (BLUs) of liquid crystal displays (LCDs) utilized in portable electronic products (e.g., mobile phones, camcorders, digital cameras, personal digital assistants (PDAs), etc.).

Lighting apparatuses are typically utilized for, for example, BLUs of LCDs. LCDs are one of the widely (e.g., most widely) utilized flat panel displays and include two display panels, on which an electric field generation electrode such as a pixel electrode and a common electrode is formed, and a liquid crystal layer therebetween. An electric field is generated in the liquid crystal layer by applying a voltage to the electric field generation electrode, the orientation of liquid crystal molecules in the liquid crystal layer is determined by the electric field, and the polarization of incident light is controlled to display an image.

An LCD utilizes a color conversion member to form a color (e.g., to provide a specific color). When light emitted from a backlight light source is transmitted through red, green, and/or blue color conversion members, the amount of light is reduced to about ⅓ by the red, green, and/or blue color conversion members, resulting in low light efficiency.

A photo-luminescent liquid crystal display (PL-LCD), which has been proposed so as to compensate for the decrease in light efficiency and improve color reproducibility, is an LCD in which a color conversion member (CCL) utilized in a related art (e.g., an existing) LCD is replaced with a quantum dot color conversion layer (QD-CCL). The PL-LCD displays color images by utilizing visible light generated when light in a low wavelength band, such as ultraviolet light and/or blue light generated from a light source and controlled by a liquid crystal layer, is irradiated onto the QD-CCL.

### SUMMARY

Aspects according to one or more embodiments are directed toward a semiconductor nanoparticle, a color conversion member including the semiconductor nanoparticle, and an electronic apparatus including the color conversion member.

Additional aspects will be set forth in part in the description which follows and, in part, will be apparent from the description, or may be learned by practice of the presented embodiments of the disclosure.

According to one or more embodiments, a semiconductor nanoparticle includes

a core including ZnSe₁₋ₓTeₓ,

a middle shell covering the core and including ZnSe and/or ZnSe_{y}S_{1-y}, and

an outer shell covering the middle shell and including a Group II-VI compound,

wherein 0.2<x≤0.5,

0<y<1, and

the semiconductor nanoparticle is to emit visible light other than blue light.

According to one or more embodiments, a color conversion member includes the semiconductor nanoparticle.

According to one or more embodiments, an electronic apparatus includes the color conversion member and a display device.

### BRIEF DESCRIPTION OF THE DRAWING

The above and other aspects, features, and enhancements of certain embodiments of the disclosure will be more apparent from the following description taken in conjunction with the accompanying drawing, in which:

The drawing is a diagram schematically illustrating a structure of a semiconductor nanoparticle according to an embodiment.

### DETAILED DESCRIPTION

Reference will now be made in more detail to embodiments, examples of which are illustrated in the accompanying drawing, wherein like reference numerals refer to like elements throughout. In this regard, the present embodiments may have different forms and should not be construed as being limited to the descriptions set forth herein. Accordingly, the embodiments are merely described below, by referring to the drawing, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the present description allows for various suitable changes and numerous embodiments, certain embodiments will be illustrated in the drawing and described in the written description. Effects and features of the disclosure, and methods for achieving them will be clarified with reference to embodiments described below in more detail with reference to the drawing. However, the disclosure is not limited to the following embodiments and may be embodied in various suitable forms.

It will be understood that although the terms “first,” “second,” etc. may be used herein to describe various suitable components, such components should not be limited by these terms. These terms are only used to distinguish one component from another.

The singular forms “a,” “an,” and “the” as used herein are intended to include the plural forms as well unless the context clearly indicates otherwise.

It will be understood that the terms “comprise,” “comprising,” “include” and/or “including” as used herein specify the presence of stated features or components but do not preclude the addition of one or more other features or components. For example, it will be understood that the terms “comprise,” “include” and/or “including” as used herein may, unless otherwise specified, refers to both the case consisting of only features or components described in this specification and the case further including other components.

Hereinafter, a semiconductor nanoparticle 10 according to an embodiment will be described with reference to the drawing.

The semiconductor nanoparticle 10 includes a core 100 including ZnSe₁₋ₓTeₓ, a middle shell 200 covering the core and including ZnSe and/or ZnSe_{y}S_{1-y} (e.g., at least one of ZnSe or ZnSe_{y}S_{1-y}), and an outer shell 300 covering the middle shell 200 and including a Group II-VI compound.

The core 100 includes ZnSe₁₋ₓTeₓ.

In ZnSe₁₋ₓTeₓ, 0.2<x≤0.5.

x represents a composition ratio of Te to Zn in ZnSe₁₋ₓTeₓ included in the core of the semiconductor nanoparticle. When x satisfies a range of greater than 0.2 and equal to or less than 0.5, the semiconductor nanoparticle may emit light having a maximum emission wavelength of about 500 nm to about 650 nm. When x is 0.2 or less, as the proportion of Te in the core of the semiconductor nanoparticle is decreased, the emission wavelength of the semiconductor nanoparticle is shortened to emit blue light. When this is applied to a color conversion member, the blue light absorption rate is low, and thus, the light emission efficiency is reduced.

According to an embodiment, the core may include two or more kinds of ZnSe₁₋ₓTeₓ in which values of x are different from each other. That is, the core may include two or more compounds represented by ZnSe₁₋ₓTeₓ, where values of x are different from each other.

For example, the core may include at least one selected from ZnSe_{0.75}Te_{0.25}, ZnSe_{0.67}Te_{0.33}, and ZnSe_{0.50}Te_{0.50}.

According to an embodiment, the core 100 may have a radius r of about 0.5 nm to about 2.5 nm, for example, about 0.6 nm to about 2.4 nm, about 0.75 nm to about 2.25 nm, or about 1 nm to about 2 nm.

According to an embodiment, 0.25≤x≤0.5.

In ZnSe_{y}S_{1-y}, 0<y<1.

y represents a composition ratio of Se to Zn in ZnSe_{y}S_{1-y} included in the middle shell 200 of the semiconductor nanoparticle.

The middle shell 200 includes ZnSe and/or ZnSe_{y}S_{1-y}.

Because the middle shell 200 includes ZnSe and/or ZnSe_{y}S_{1-y}, structural defects due to crystal non-bonding of the middle shell 200 to the core including ZnSe₁₋ₓTeₓ are reduced, and thus, the thickness of the middle shell 200 may be sufficiently formed, so that the inner core may be protected.

According to an embodiment, the middle shell 200 may include ZnSe.

According to an embodiment, the middle shell 200 may include ZnSe_{y}S_{1-y}. Also, according to an embodiment, the middle shell 200 may include two or more kinds of ZnSe_{y}S_{1-y} in which values of y are different from each other. That is, the middle shell 200 may include two or more compounds represented by ZnSe_{y}S_{1-y}, where values of y are different from each other.

For example, the middle shell 200 may include at least one selected from ZnSe, ZnSe_{0.75}S_{0.25}, ZnSe_{0.67}S_{0.33}, ZnSe_{0.50}S_{0.50}, and ZnSe_{0.33}S_{0.67}.

According to an embodiment, an interface between the core 100 and the middle shell 200 may have a concentration gradient in which the concentration of elements present in the middle shell 200 decreases toward the center of the semiconductor particle 10.

According to an embodiment, the middle shell 200 may have a thickness l of about 0.5 nm to about 2 nm, for example, about 0.6 nm to about 1.9 nm, about 0.7 nm to about 1.8 nm, about 1.0 nm to about 1.7 nm, or about 1.2 nm to about 1.5 nm.

The outer shell 300 includes a Group II-VI compound.

According to an embodiment, the Group II-VI compound may include Zn.

According to an embodiment, the Group II-VI compound may include a binary compound or a tertiary compound.

For example, the Group II-VI compound may include at least one compound selected from ZnS, ZnSe, ZnTe, ZnO, ZnSeS, ZnSeTe, and ZnSTe.

For example, the Group II-VI compound may include ZnS.

According to an embodiment, an interface between the middle shell 200 and the outer shell 300 may have a concentration gradient in which the concentration of elements present in the outer shell 300 decreases toward the center of the semiconductor particle 10.

According to an embodiment, the outer shell 300 may have a thickness h of about 0.5 nm to about 2 nm, for example, about 0.6 nm to about 1.9 nm, about 0.7 nm to about 1.8 nm, about 1.0 nm to about 1.7 nm, or about 1.2 nm to about 1.5 nm.

The middle shell 200 and the outer shell 300 of the semiconductor nanoparticle 10 may serve as a protective layer for reducing or preventing chemical modification of the core 100 and for maintaining semiconductor properties and/or a charging layer for imparting electrophoretic properties to the semiconductor nanoparticle 10.

The semiconductor nanoparticle 10 may emit visible light other than blue light. For example, the semiconductor nanoparticle 10 may emit light having a maximum emission wavelength of about 500 nm to about 650 nm. Therefore, when the semiconductor nanoparticle 10 is applied to a color conversion member, it may be designed to absorb blue light and emit wavelengths in various suitable color ranges.

According to an embodiment, the semiconductor nanoparticle 10 may emit green light having a maximum emission wavelength of about 500 nm to about 600 nm. Therefore, when the semiconductor nanoparticle 10 is applied to a color conversion member, green light with high luminance and high color purity may be implemented (e.g., produced).

According to an embodiment, the semiconductor nanoparticle 10 may have a diameter 2R of about 3 nm to about 13 nm. For example, the semiconductor nanoparticle 10 may have a diameter 2R of about 4 nm to about 12 nm, for example, about 5 nm to about 11 nm, about 6 nm to about 10 nm, or about 7 nm to about 9 nm.

According to an embodiment, the semiconductor nanoparticle 10 may have an absorbance of about 0.1 or greater, for example, 0.15 or greater with respect to blue light having a wavelength of about 450 nm. Therefore, when the semiconductor nanoparticle 10 is applied to an optical conversion layer of a lighting apparatus, a high absorption rate for blue light from a light source enables high-efficiency optical conversion and high-purity green light may be implemented.

According to an embodiment, the semiconductor nanoparticle 10 may have a full width of half maximum (FWHM) of an emission wavelength spectrum in a range of about 60 nm or less, for example, about 55 nm or less. When the FWHM of the semiconductor nanoparticle 10 is within the above-described ranges, color purity and color reproducibility may be suitable (e.g., excellent) and a wide viewing angle may be improved (e.g., the viewing angle may be wider).

In related art (e.g., existing) InP/ZnSe₁₋ₐSₐ core-shell quantum dots (wherein a is an integer of 0 or 1), blue excited light of 450 nm is efficiently absorbed only in the InP core layer, and only a portion of ZnSe absorbs blue excited light. Therefore, in the case of green quantum dots in which the size of InP is small, the absorption rate for blue light may be sufficiently increased when the ZnSe shell is formed to be thicker. In this case, however, structural defects may occur due to crystal non-bonding (e.g., poor bonding) between the InP core and the ZnSe shell.

The semiconductor nanoparticle 10 according to embodiments may have suitable (e.g., excellent) absorbance for blue light, the generation of defects at the interface between the core and the shell may be reduced, and the shell having a sufficient thickness may be utilized to implement (e.g., realize) high light efficiency and high color purity while protecting the core of the semiconductor nanoparticle 10.

According to an embodiment, the shape of the semiconductor nanoparticle 10 is not particularly limited, and the semiconductor particle 10 may have shapes that are commonly utilized in the related art. For example, the semiconductor nanoparticle 10 may have a shape such as spherical, pyramidal, multi-arm, or cubic nanoparticles, nanotubes, nanowires, nanofibers, nanoplatelet particles, and/or the like.

According to an embodiment, the semiconductor nanoparticle 10 may further include other compounds in addition to the above-described composition.

For example, the semiconductor nanoparticle 10 may further include a Group II-VI compound, a Group III-VI compound, a Group III-V compound, a Group IV-VI compound, a Group IV element or compound, a Group I-III-VI compound, or any combination thereof in the core 100, the middle shell 200, or the outer shell 300.

The Group II-VI compound may be selected from: a binary compound selected from CdS, CdSe, CdTe, ZnS, ZnSe, ZnTe, ZnO, HgS, HgSe, HgTe, MgSe, MgS, and any mixture (e.g., combination) thereof; a ternary compound selected from CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and any mixture (e.g., combination) thereof; and a quaternary compound selected from CdZnSeS, CdZnSeTe, CdZnSTe, CdHgSeS, CdHgSeTe, CdHgSTe, HgZnSeS, HgZnSeTe, HgZnSTe, and any mixture (e.g., combination) thereof.

The Group III-VI compound may include a binary compound such as In₂S₃ and/or In₂Se₃, a ternary compound such as InGaS₃ and/or InGaSe₃, or any combination thereof.

The Group III-V compound may be selected from: a binary compound selected from GaN, GaP, GaAs, GaSb, AlN, AlP, AlAs, AlSb, InN, InP, InAs, InSb, and any mixture (e.g., combination) thereof; a ternary compound selected from GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, GaAlNP, and any mixture (e.g., combination) thereof; and a quaternary compound selected from GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and any mixture (e.g., combination) thereof. The Group III-V semiconductor compound may further include a Group II metal (e.g., InZnP, etc.).

The Group IV-VI compound may be selected from: a binary compound selected from SnS, SnSe, SnTe, PbS, PbSe, PbTe, and any mixture (e.g., combination) thereof; a ternary compound selected from SnSeS, SnSeTe, SnSTe, PbSeS, PbSeTe, PbSTe, SnPbS, SnPbSe, SnPbTe, and any mixture (e.g., combination) thereof; and a quaternary compound selected from SnPbSSe, SnPbSeTe, SnPbSTe, and any mixture (e.g., combination) thereof. The Group IV element may be selected from Si, Ge, and any mixture thereof. The Group IV element may include a binary compound selected from SiC, SiGe, and any mixture (e.g., combination) thereof.

The Group I-III-VI semiconductor compound may include a ternary compound such as AgInS, AgInS₂, CuInS, CuInS₂, CuGaO₂, AgGaO₂, AgAlO₂, or any combination thereof.

The binary compound, the ternary compound, or the quaternary compound may be present in particles at a uniform concentration, or may be present in the same particles in partially different concentration distributions (e.g., at a non-uniform concentration).

According to an embodiment, the middle shell 200 and/or the outer shell 300 may further include a metal oxide or a non-metal oxide, a semiconductor compound, or any combination thereof.

For example, the metal oxide or non-metal oxide may include a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, and/or NiO, and/or a ternary compound such as MgAl₂O₄, CoFe₂O₄, NiFe₂O₄, and/or CoMn₂O₄.

Also, for example, the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, and/or AlSb.

According to an embodiment, a method of manufacturing the semiconductor nanoparticle is provided.

The method of manufacturing the semiconductor nanoparticle may include:

preparing a mixture of a Zn precursor and a solvent;

forming a core including ZnSe₁₋ₓTeₓ by adding a Se precursor and a Te precursor to the mixture;

forming a middle shell covering the core and including ZnSe and/or ZnSe_{y}S_{1-y}; and

forming an outer shell covering the middle shell and including a Group II-VI compound.

According to an embodiment, the preparing of the mixture of the Zn precursor and the solvent may include heating the mixture. For example, the mixture may be heated to a temperature of about 80° C. to about 140° C.

According to an embodiment, the forming of the core may include adding a Se precursor and a Te precursor to the mixture and heating the reaction product (e.g., the mixture including the Zn precursor and the solvent, the Se precursor and the Te precursor) to a reaction temperature. According to an embodiment, the reaction temperature for forming the core may be in a range of about 100° C. to about 320° C., for example, about 130° C. to about 300° C., or about 170° C. to about 270° C.

According to an embodiment, the solvent may be an organic solvent. For example, the solvent may utilize trioctylamine, oleylamine, 1-octadecene, and/or the like.

Details of the method of manufacturing the semiconductor nanoparticle may be recognized by those of ordinary skill in the art with reference to the following examples.

According to an embodiment, a color conversion member including the semiconductor nanoparticle is provided.

According to an embodiment, at least one region of the color conversion member may include the semiconductor nanoparticle, and the semiconductor nanoparticle may absorb blue light and emit visible light other than blue light, for example, visible light having a maximum emission wavelength of about 500 nm to about 650 nm. Therefore, the color conversion member including the semiconductor nanoparticle may be designed to absorb blue light and emit wavelengths in various suitable color ranges.

According to an embodiment, at least one region of the color conversion member may include the semiconductor nanoparticle, and the semiconductor nanoparticle may absorb blue light and emit green light having a maximum emission wavelength of about 500 nm to about 600 nm. Therefore, the color conversion member including the semiconductor nanoparticle may implement (e.g., produce) green light with high luminance and high color purity.

According to an embodiment, an electronic apparatus including the color conversion member and the display device is provided.

According to an embodiment, the display device may emit blue light having a maximum emission wavelength of about 400 nm to about 490 nm.

According to an embodiment, at least one region of the color conversion member in the electronic apparatus may include the semiconductor nanoparticle, and the at least one region of the color conversion member may absorb blue light emitted from the display device and emit visible light other than blue light, for example, visible light having a maximum emission wavelength of about 500 nm to about 650 nm. Therefore, the color conversion member including the semiconductor nanoparticle may be designed to absorb blue light emitted from the display device and emit wavelengths in various suitable color ranges.

According to an embodiment, at least one region of the color conversion member in the electronic apparatus may include the semiconductor nanoparticle, and the at least one region of the color conversion member may absorb blue light emitted from the display device and emit green light having a maximum emission wavelength of about 500 nm to about 600 nm. Therefore, the color conversion member including the semiconductor nanoparticle may absorb blue light emitted from the display device, thereby implementing (e.g., producing) green light with high luminance and high color purity.

According to an embodiment, the display device may include an LCD, an organic light-emitting display device, or an inorganic-light emitting display device.

Hereinafter, the semiconductor nanoparticle according to the embodiment will be described in more detail with reference to examples.

### EXAMPLES

### Example 1: Synthesis of ZnSe_{0.67}Te_{0.33}/ZnSe/ZnS Semiconductor Nanoparticle

0.6 mmol of zinc oleate and 10 mL of 1-octadecene were added to a three-neck flask and a vacuum state was maintained at a temperature of 110° C. for 1 hour. After the vacuum was released, the three-neck flask was filled with an inert gas and heated to a temperature of 230° C. After 0.2 mmol of diphenylphosphine selenide was added at a temperature of 230° C., 0.1 mmol of trioctylphosphine telluride was added, reacted for 30 minutes, heated to a temperature of 300° C., and reacted for 15 minutes.

Then, 1 mmol of zinc oleate and 1 mmol of trioctylphosphine selenide were added and reacted for 1 hour to form a zinc selenide shell.

Afterwards, 2 mmol of zinc oleate and 2 mmol of trioctylphosphine sulfide were added and reacted for 1 hour to form a zinc sulfide shell. In this manner, a semiconductor nanoparticle of Example 1 was obtained.

### Example 2: Synthesis of ZnSe_{0.75}Te_{0.25}/ZnSe/ZnS Semiconductor Nanoparticle

0.6 mmol of zinc oleate and 10 mL of 1-octadecene were added to a three-neck flask and a vacuum state was maintained at a temperature of 110° C. for 1 hour. After the vacuum was released, the three-neck flask was filled with an inert gas and heated to a temperature of 230° C. After 0.225 mmol of diphenylphosphine selenide was added at a temperature of 230° C., 0.075 mmol of trioctylphosphine telluride was added, reacted for 30 minutes, heated to a temperature of 300° C., and reacted for 15 minutes. In a subsequent process, a zinc selenide shell and a zinc sulfide shell were sequentially formed in the same manner as in Example 1 to obtain a semiconductor nanoparticle of Example 2.

### Example 3: Synthesis of ZnSe_{0.5}Te_{0.5}/ZnSe/ZnS Semiconductor Nanoparticle

0.6 mmol of zinc oleate and 10 mL of 1-octadecene were added to a three-neck flask and a vacuum state was maintained at a temperature of 110° C. for 1 hour. After the vacuum was released, the three-neck flask was filled with an inert gas and heated to a temperature of 230° C. After 0.15 mmol of diphenylphosphine selenide was added at a temperature of 230° C., 0.15 mmol of trioctylphosphine telluride was added, reacted for 30 minutes, heated to a temperature of 300° C., and reacted for 15 minutes. In a subsequent process, a zinc selenide shell and a zinc sulfide shell were sequentially formed in the same manner as in Example 1 to obtain a semiconductor nanoparticle of Example 3.

### Example 4: Synthesis of ZnSe_{0.67}Te_{0.33}/ZnSe_{0.67}S_{0.33}/ZnS Semiconductor Nanoparticle

0.6 mmol of zinc oleate and 10 mL of 1-octadecene were added to a three-neck flask and a vacuum state was maintained at a temperature of 110° C. for 1 hour. After the vacuum was released, the three-neck flask was filled with an inert gas and heated to a temperature of 230° C. After 0.2 mmol of diphenylphosphine selenide was added at a temperature of 230° C., 0.1 mmol of trioctylphosphine telluride was added, reacted for 30 minutes, heated to a temperature of 300° C., and reacted for 15 minutes.

Then, 1 mmol of zinc oleate, 0.66 mmol of trioctylphosphine selenide, and 0.33 mmol of trioctylphosphine sulfide were added and reacted for 1 hour to form a zinc selenide sulfide alloy shell.

Afterwards, 2 mmol of zinc oleate and 2 mmol of trioctylphosphine sulfide were added and reacted for 1 hour to form a zinc sulfide shell. In this manner, a semiconductor nanoparticle of Example 4 was obtained.

### Example 5: Synthesis of ZnSe_{0.67}Te_{0.33}/ZnSe_{0.33}S_{0.67}/ZnS Semiconductor Nanoparticle

0.6 mmol of zinc oleate and 10 mL of 1-octadecene were added to a three-neck flask and a vacuum state was maintained at a temperature of 110° C. for 1 hour. After the vacuum was released, the three-neck flask was filled with an inert gas and heated to a temperature of 230° C. After 0.2 mmol of diphenylphosphine selenide was added at a temperature of 230° C., 0.1 mmol of trioctylphosphine telluride was added, reacted for 30 minutes, heated to a temperature of 300° C., and reacted for 15 minutes.

Then, 1 mmol of zinc oleate, 0.33 mmol of trioctylphosphine selenide, and 0.66 mmol of trioctylphosphine sulfide were added and reacted for 1 hour to form a zinc selenide sulfide alloy shell.

Afterwards, 2 mmol of zinc oleate and 2 mmol of trioctylphosphine sulfide were added and reacted for 1 hour to form a zinc sulfide shell. In this manner, a semiconductor nanoparticle of Example 5 was obtained.

### Comparative Example 1: Synthesis of ZnSe_{0.95}Te_{0.05}/ZnSe/ZnS Semiconductor Nanoparticle

0.6 mmol of zinc oleate and 10 mL of 1-octadecene were added to a three-neck flask and a vacuum state was maintained at a temperature of 110° C. for 1 hour. After the vacuum was released, the three-neck flask was filled with an inert gas and heated to a temperature of 230° C. After 0.285 mmol of diphenylphosphine selenide was added at a temperature of 230° C., 0.015 mmol of trioctylphosphine telluride was added, reacted for 30 minutes, heated to a temperature of 300° C., and reacted for 15 minutes. In a subsequent process, a zinc selenide shell and a zinc sulfide shell were sequentially formed in the same manner as in Example 1 to obtain a semiconductor nanoparticle of Comparative Example 1.

### Comparative Example 2: Synthesis of ZnSe_{0.92}Te_{0.08}/ZnSe/ZnS Semiconductor Nanoparticle

0.6 mmol of zinc oleate and 10 mL of 1-octadecene were added to a three-neck flask and a vacuum state was maintained at a temperature of 110° C. for 1 hour. After the vacuum was released, the three-neck flask was filled with an inert gas and heated to a temperature of 230° C. After 0.276 mmol of diphenylphosphine selenide was added at a temperature of 230° C., 0.024 mmol of trioctylphosphine telluride was added, reacted for 30 minutes, heated to a temperature of 300° C., and reacted for 15 minutes. In a subsequent process, a zinc selenide shell and a zinc sulfide shell were sequentially formed in the same manner as in Example 1 to obtain a semiconductor nanoparticle of Comparative Example 2.

### Comparative Example 3: Synthesis of ZnSe_{0.84}Te_{0.16}/ZnSe/ZnS Semiconductor Nanoparticle

0.6 mmol of zinc oleate and 10 mL of 1-octadecene were added to a three-neck flask and a vacuum state was maintained at a temperature of 110° C. for 1 hour. After the vacuum was released, the three-neck flask was filled with an inert gas and heated to a temperature of 230° C. After 0.252 mmol of diphenylphosphine selenide was added at a temperature of 230° C., 0.048 mmol of trioctylphosphine telluride was added, reacted for 30 minutes, heated to a temperature of 300° C., and reacted for 15 minutes. In a subsequent process, a zinc selenide shell and a zinc sulfide shell were sequentially formed in the same manner as in Example 1 to obtain a semiconductor nanoparticle of Comparative Example 3.

### Evaluation Example 1

The maximum emission wavelength, FWHM, emission quantum yield, and absorbance for blue light having a wavelength of 450 nm were evaluated for each of the semiconductor nanoparticles manufactured in Examples 1 to 5 and Comparative Examples 1 to 3, and results thereof are shown in Table 1.

The measurement method is as follows: For a 1 mg/ml solution of the semiconductor nanoparticles of each of Examples 1 to 5 and Comparative Examples 1 to 3, the maximum emission wavelength, FWHM, and absorbance for blue light were evaluated by analyzing the photoluminescence (PL) spectrum and absorbance measured by utilizing a PL spectrometer and a UV-vis spectrometer. The emission quantum yield was evaluated by utilizing an absolute quantum efficiency measurement apparatus.

TABLE 1

| | | Maximum | | Emission | |
|---|---|---|---|---|---|
| | | emission | | quantum | |
| | Semiconductor | wavelength | FWHM | efficiency | Absorbance |
| | nanoparticle | (nm) | (nm) | (%) | @450 nm |
| Example | ZnSe_{0.66}Te_{0.33}/ZnSe/ZnS | 515 | 49 | 86 | 0.21 |
| 1 | | | | | |
| Example | ZnSe_{0.75}Te_{0.25}/ZnSe/ZnS | 525 | 45 | 83 | 0.15 |
| 2 | | | | | |
| Example | ZnSe_{0.50}Te_{0.50}/ZnSe/ZnS | 553 | 40 | 47 | 0.31 |
| 3 | | | | | |
| Example | ZnSe_{0.66}Te_{0.33}/ZnSe_{0.67}S_{0.33}/ZnS | 518 | 44 | 62 | 0.20 |
| 4 | | | | | |
| Example | ZnSe_{0.66}Te_{0.33}/ZnSe_{0.33}S_{0.67}/ZnS | 511 | 49 | 16 | 0.19 |
| 5 | | | | | |
| Com- | ZnSe_{0.95}Te_{0.05}/ZnSe/ZnS | 433 | 47 | 80 | 0 |
| parative | | | | | |
| Example | | | | | |
| 1 | | | | | |
| Com- | ZnSe_{0.92}Te_{0.08}/ZnSe/ZnS | 450 | 53 | 82 | 0 |
| parative | | | | | |
| Example | | | | | |
| 2 | | | | | |
| Com- | ZnSe_{0.84}Te_{0.16}/ZnSe/ZnS | 473 | 48 | 81 | 0.08 |
| parative | | | | | |
| Example | | | | | |
| 3 | | | | | |

From Table 1, it was confirmed that the semiconductor nanoparticles of Examples 1 to 5 each had a narrower FWHM and had suitable (e.g., excellent) light emission quantum yield and suitable (e.g., excellent) absorbance for blue light. Also, it was confirmed that the semiconductor nanoparticles of Examples 1 to 5 each had high absorbance for blue light, as compared with each of the semiconductor nanoparticles of Comparative Examples 1 to 3. Also, it was confirmed that the semiconductor nanoparticles of Comparative Examples 1 to 3 each emitted blue light, whereas the semiconductor nanoparticles of Examples 1 to 5 each emitted visible light having a maximum emission wavelength of 500 nm or greater.

The semiconductor nanoparticle may have a high blue light absorption rate and may have suitable (e.g., excellent) light efficiency because structural defects caused by crystal non-bonding between the core and the shell are reduced. Therefore, the color conversion member including the semiconductor nanoparticle may have suitable (e.g., excellent) light conversion efficiency and may implement (e.g., realize) high color purity.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the FIGURES, it will be understood by those of ordinary skill in the art that various suitable changes in form and details may be made therein without departing from the spirit and scope as defined by the following claims, and equivalents thereof.

What is claimed is:

1. A semiconductor nanoparticle comprising:
a core comprising ZnSe₁₋ₓTeₓ;
a middle shell covering the core and comprising ZnSe and/or ZnSe_{y}S_{1-y}; and
an outer shell covering the middle shell and comprising a Group II-VI compound,
wherein 0.2<x≤0.5,
0<y<1, and
the semiconductor nanoparticle is to emit visible light other than blue light.

2. The semiconductor nanoparticle of claim 1, wherein 0.25≤x≤0.5.

3. The semiconductor nanoparticle of claim 1, wherein the semiconductor nanoparticle is to emit light having a maximum emission wavelength of about 500 nm to about 650 nm.

4. The semiconductor nanoparticle of claim 1, wherein the semiconductor nanoparticle is to emit green light having a maximum emission wavelength of about 500 nm to about 600 nm.

5. The semiconductor nanoparticle of claim 1, wherein the Group II-VI compound comprises Zn, and is a binary compound or a ternary compound.

6. The semiconductor nanoparticle of claim 1, wherein the Group II-VI compound comprises at least one compound selected from ZnS, ZnSe, ZnTe, ZnO, ZnSeS, ZnSeTe, and ZnSTe.

7. The semiconductor nanoparticle of claim 1, wherein the Group II-VI compound comprises ZnS.

8. The semiconductor nanoparticle of claim 1, wherein the core is about 0.5 nm to about 2.5 nm in radius.

9. The semiconductor nanoparticle of claim 1, wherein the middle shell is about 0.5 nm to about 2 nm in thickness.

10. The semiconductor nanoparticle of claim 1, wherein the outer shell is about 0.5 nm to about 2 nm in thickness.

11. The semiconductor nanoparticle of claim 1, wherein the semiconductor nanoparticle is about 3 nm to about 13 nm in diameter.

12. The semiconductor nanoparticle of claim 1, wherein the semiconductor nanoparticle has an absorbance of about 0.1 or greater with respect to blue light having a wavelength of about 450 nm.

13. The semiconductor nanoparticle of claim 1, wherein an emission wavelength spectrum of the semiconductor nanoparticle has a full width of half maximum (FWHM) in a range of about 60 nm or less.

14. A color conversion member comprising:
a semiconductor nanoparticle, wherein the semiconductor nanoparticle comprises:
a core comprising ZnSe₁₋ₓTeₓ;
a middle shell covering the core and comprising ZnSe and/or ZnSe_{y}S_{1-y}; and
an outer shell covering the middle shell and comprising a Group II-VI compound, and
wherein 0.2<x≤0.5,
0<y<1, and
the semiconductor nanoparticle is to emit visible light other than blue light.

15. An electronic apparatus comprising the color conversion member of claim 14 and a display device.

16. The electronic apparatus of claim 15, wherein the display device is to emit blue light having a maximum emission wavelength of about 400 nm to about 490 nm.

17. The electronic apparatus of claim 16, wherein at least one region of the color conversion member comprises the semiconductor nanoparticle, and the at least one region of the color conversion member is to absorb blue light emitted from the display device and to emit visible light other than blue light.

18. The electronic apparatus of claim 16, wherein at least one region of the color conversion member comprises the semiconductor nanoparticle, and the at least one region of the color conversion member is to absorb blue light emitted from the display device and to emit light having a maximum emission wavelength of about 500 nm to about 650 nm.

19. The electronic apparatus of claim 16, wherein at least one region of the color conversion member comprises the semiconductor nanoparticle, and the at least one region of the color conversion member is to absorb blue light emitted from the display device and to emit green light having a maximum emission wavelength of about 500 nm to about 600 nm.

20. The electronic apparatus of claim 15, wherein the display device comprises a liquid crystal display, an organic light-emitting display device, or an inorganic-light emitting display device.
